(19) United States
(12) Patent Application Publication
(10) Pub. No.: US 2026/0052733 A1
(43) Pub. Date: Feb. 19, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Tsung-Chieh HSIAO, Changhua (TW); Wei-Yuan LEE, Hsinchu (TW); Chih-Lin WANG, Hsinchu (TW)

(21) Appl. No.: 18/807,924

(22) Filed: Aug. 17, 2024

(51) Int. Cl. H01L 29/423; H01L 21/8238; H01L 27/092; H01L 29/06; H01L 29/49; H01L 29/66; H01L 29/775; H01L 29/786

(52) U.S. Cl. CPC H10D 30/6735; H10D 30/014; H10D 30/43; H10D 30/6757; H10D 62/121; H10D 64/667; H10D 84/0167; H10D 84/0172; H10D 84/038; H10D 84/85

(57) ABSTRACT

Embodiments of the present disclosure provide semiconductor device structures and methods of forming the same. The structure includes a first semiconductor layer disposed in a first region over a substrate, a gate dielectric layer disposed over the first semiconductor layer in the first region, one or more work function layers disposed on the gate dielectric layer in the first region, a gate electrode layer disposed on the one or more work function layers in the first region, and a second semiconductor layer disposed in a second region over the substrate. The gate dielectric layer is disposed over the second semiconductor layer in the second region, and the gate electrode layer is disposed on the gate dielectric layer in the second region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of one of various stages of manufacturing a semiconductor device structure, in accordance with some embodiments.

FIGS. 2A, 2B, 2C, and 2D are cross-sectional side views of various stages of manufacturing the semiconductor device structure taken along line A-A of FIG. 1, in accordance with some embodiments.

FIGS. 3A, 4A, 5A, 6A, 7A, and 8A are cross-sectional side views of various stages of manufacturing the semiconductor device structure taken along line A-A of FIG. 1, in accordance with some embodiments.

FIGS. 3B, 4B, 5B, 6B, 7B, and 8B are cross-sectional side views of various stages of manufacturing the semiconductor device structure taken along line B-B of FIG. 1, in accordance with some embodiments.

FIGS. 9A, 9B, 9C, 9D, and 9E are cross-sectional side views of various stages of manufacturing the semiconductor device structure, in accordance with some embodiments.

FIGS. 10A, 10B, 10C, 10D, 10E, 10F, 10G, and 10H are cross-sectional side views of various stages of manufacturing the semiconductor device structure, in accordance with alternative embodiments.

FIGS. 11A, 11B, 11C, 11D, 11E, and 11F are cross-sectional side views of various stages of manufacturing the semiconductor device structure, in accordance with alternative embodiments.

FIG. 12 is a top view of the semiconductor device structure, in accordance with some embodiments.

FIGS. 13A, 13B, 13C, and 13D are cross-sectional side views of the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as Horizontal Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

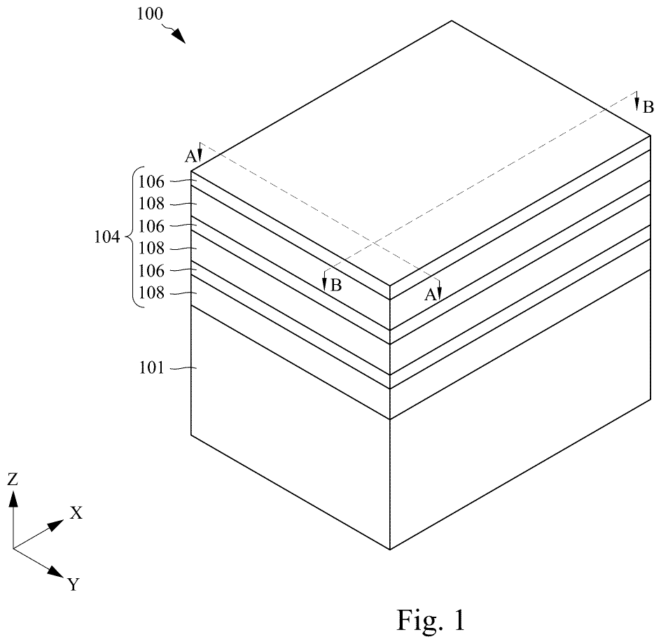

FIG. 1-9E show exemplary processes for manufacturing a semiconductor device structure 100 according to embodiments of the present disclosure. It is understood that additional operations can be provided before, during, and after processes shown by FIG. 1-9E, and some of the operations described below can be replaced or eliminated, for additional embodiments of the method. The order of the operations/processes is not limiting and may be interchangeable.

FIG. 1 is a perspective view of one of various stages of manufacturing a semiconductor device structure 100, in accordance with some embodiments. As shown in FIG. 1, a semiconductor device structure 100 includes a stack of semiconductor layers 104 formed over a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type impurities). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

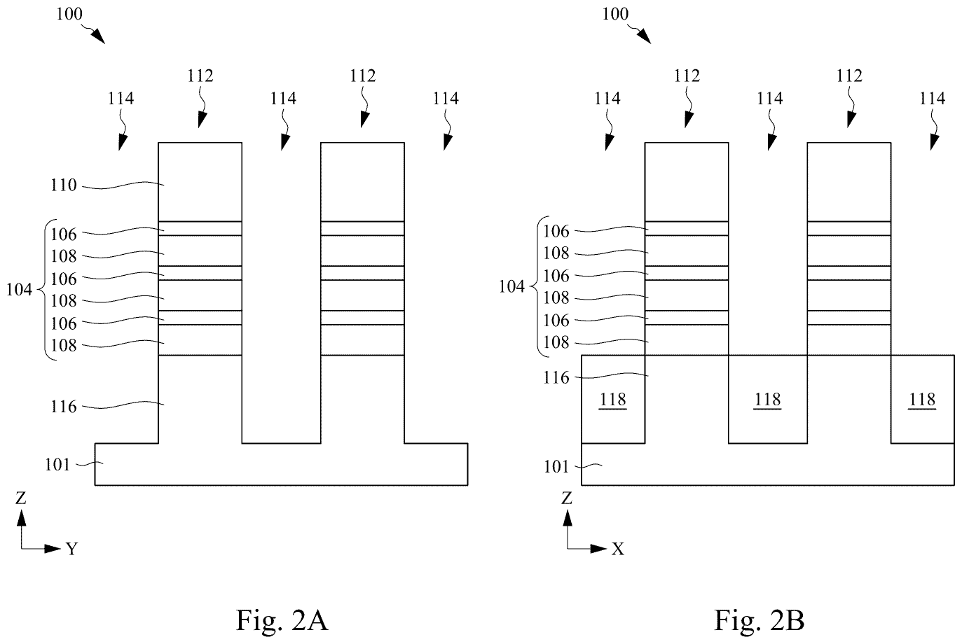

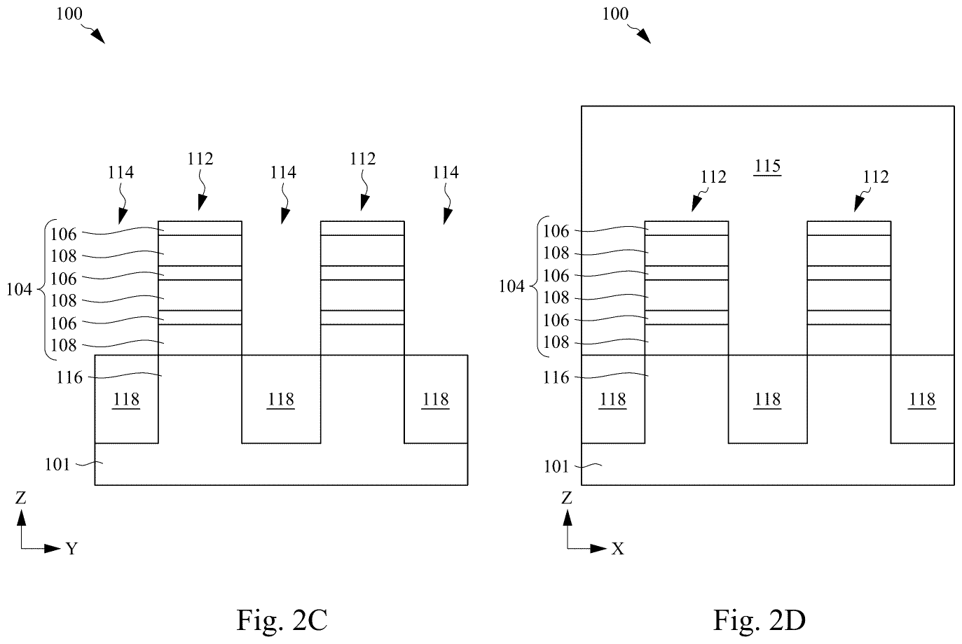

FIG. 2A-2D are cross-sectional side views of various stages of manufacturing the semiconductor device structure 100 taken along line A-A of FIG. 1, in accordance with some embodiments. As shown in FIG. 2A, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer 110 formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer 110, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer 110, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

In FIG. 2B, after the fin structures 112 are formed, isolation regions 118 are formed on the substrate 101. The isolation regions 118 may be formed by first filling the trenches 114 between neighboring fin structures 112 with an insulating material. The insulating material is then recessed to form isolation regions 118. The recess of the insulating material exposes portions of the fin structures 112, such as the stack of semiconductor layers 104. The recess of the insulating material reveals the trenches 114 between the neighboring fin structures 112. A top surface of the isolation region 118 may be level with or below a surface of the second semiconductor layers 108 in contact with the substrate portion 116 formed from the substrate 101. The isolation regions 118 may be made of silicon oxide, silicon nitride, silicon oxynitride (SiON), SiOCN, SiCN, fluorine-doped silicate glass (FSG), a low-K dielectric material, or any suitable dielectric material. The isolation regions 118 may be formed by any suitable method, such as low-pressure chemical vapor deposition (LPCVD), plasma enhanced CVD (PECVD) or flowable CVD (FCVD).

As shown in FIG. 2C, the hard mask layer 110 is removed. The hard mask layer 110 may be removed by a selective etch process that does not substantially affect the isolation regions 118 and the stack of semiconductor layers 104. As shown in FIG. 2D, a sacrificial gate material 115 is formed on the fin structures 112 and the isolation regions 118. A sacrificial gate dielectric layer (not shown) may be first formed on the fin structures 112 and the isolation regions 118, and the sacrificial gate material 115 is formed on the sacrificial gate dielectric layer.

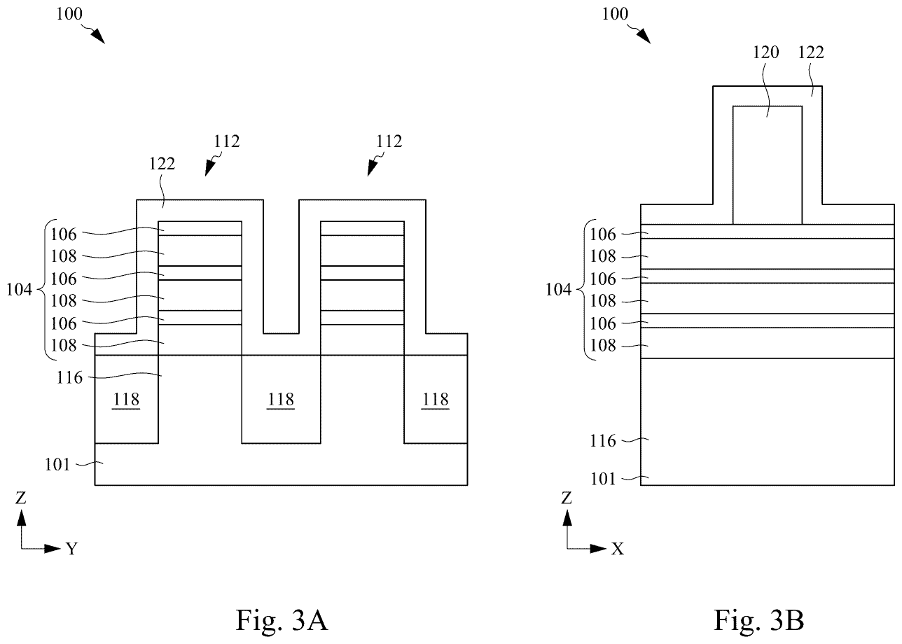

FIG. 3A-8A are cross-sectional side views of various stages of manufacturing the semiconductor device structure 100 taken along line A-A of FIG. 1, in accordance with some embodiments. The line A-A illustrates a cross-section in the source/drain (S/D) regions. FIG. 3B-8B are cross-sectional side views of various stages of manufacturing the semiconductor device structure 100 taken along line B-B of FIG. 1, in accordance with some embodiments. The line B-B illustrates a cross-section along a fin structure 112. As shown in FIGS. 3A and 3B, the one or more sacrificial gate electrodes 120 (only one is shown) are formed across one or more fin structures 112. The one or more sacrificial gate electrodes 120 may be formed by patterning the sacrificial gate material 115. The sacrificial gate dielectric layer may be also patterned along with the sacrificial gate material 115. In some embodiments, the sacrificial gate electrode 120 and the sacrificial gate dielectric layer together may form a sacrificial gate structure. Each sacrificial gate structure may be formed over a portion of the fin structures 112. While one sacrificial gate structure is shown, two or more sacrificial gate structures may be arranged along the X direction in some embodiments.

In some embodiments, a mask layer (not shown) may be formed on the sacrificial gate electrode 120, and the mask layer is part of the sacrificial gate structure. The sacrificial gate dielectric layer may include one or more layers of dielectric material, such as a silicon oxide-based material. The sacrificial gate electrode 120 may include silicon, such as polycrystalline silicon or amorphous silicon. The mask layer may include more than one layer, such as an oxide layer and a nitride layer.

As shown in FIGS. 3A and 3B, gate spacers 122 are then formed on the sacrificial gate structures and the exposed portions of the fin structures 112. The gate spacers 122 may include one or more conformal layers. The gate spacer 122 may be made of a dielectric material such as silicon oxide, silicon nitride, silicon carbide, silicon oxynitride, SiCN, silicon oxycarbide, SiOCN, and/or combinations thereof. In some embodiments, a native oxide layer may be formed on the topmost semiconductor layer 106, and the gate spacer 122 is deposited on the native oxide layer.

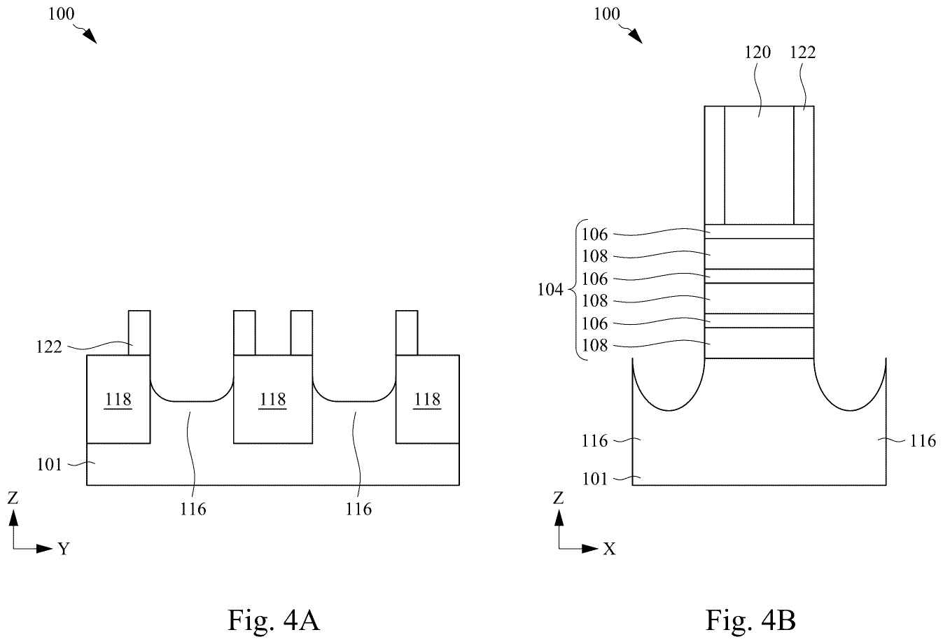

Next, as shown in FIGS. 4A and 4B, an anisotropic etch process is performed to remove portions of the gate spacers 122 formed on horizontal surfaces, and the exposed portions of the fin structures 112 not covered by the sacrificial gate structures are recessed. The portions of the fin structures 112 that are covered by the sacrificial gate electrode 120 of the sacrificial gate structure serve as channel regions for the semiconductor device structure 100.

The portions of the fin structures 112 not covered by the sacrificial gate structure and the gate spacers 122 are recessed to a level above, at, or below the top surfaces of the isolation regions 118. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. After recessing the exposed portion of each fin structure 112, a portion of each substrate portion 116 is exposed.

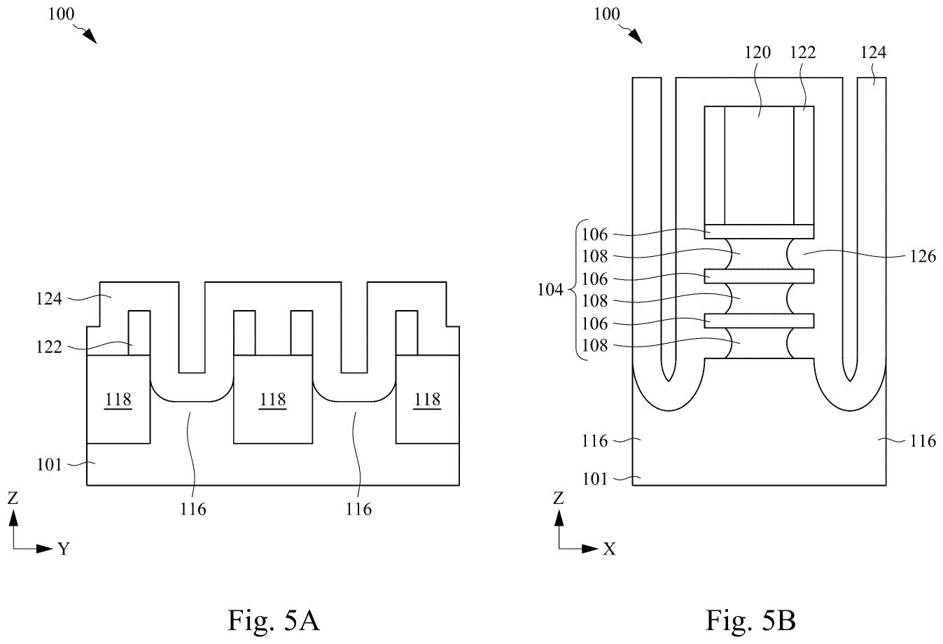

Next, as shown in FIGS. 5A and 5B, edge portions of each second semiconductor layer 108 of the stack of semiconductor layers 104 are removed horizontally along the X direction, and a dielectric layer 124 is deposited on the exposed surfaces of the semiconductor device structure 100. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

The dielectric layer 124 may be made of a dielectric material, such as SiON, SiCN, SiOC, SiOCN, SiN, SIO2, AlO, or HfO. In some embodiments, the dielectric material is a low-K dielectric material (with K value less than 7). In some embodiments, the dielectric material is a high-K dielectric material (with K value greater than or equal to 7). The dielectric layer 124 may be formed by a conformal deposition process, such as ALD. Portions of the dielectric layer 124 formed in the cavities created by the removal of the edge portions of the second semiconductor layers 108 may be dielectric spacers 126, as shown in FIG. 5B.

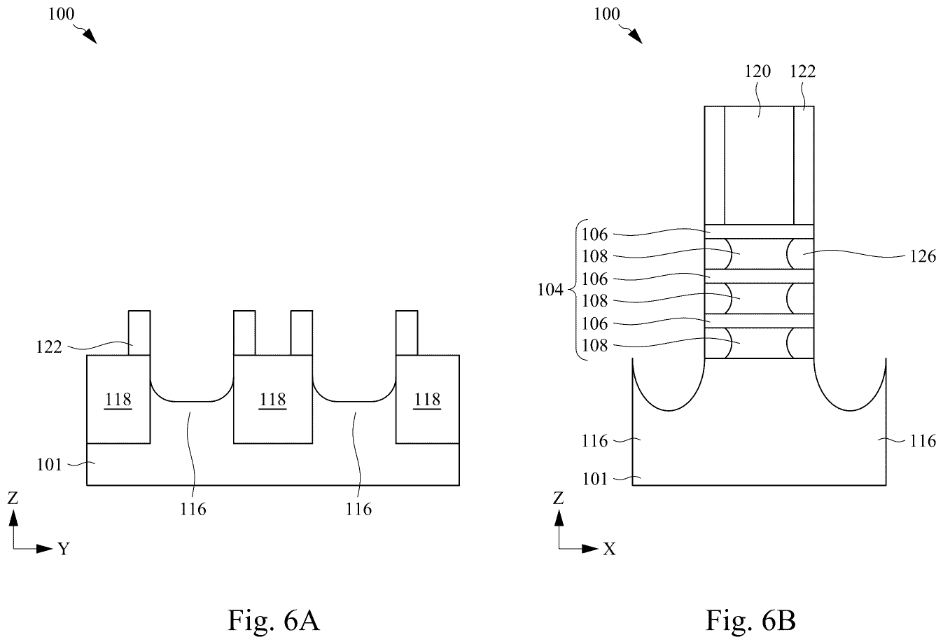

As shown in FIGS. 6A and 6B, portions of the dielectric layer 124 are removed by an anisotropic etch process. As a result, the dielectric spacers 126 are not removed because the dielectric spacers 126 are protected by the first semiconductor layers 106 during the anisotropic etch process. The remaining second semiconductor layers 108 are capped between the dielectric spacers 126 along the X direction.

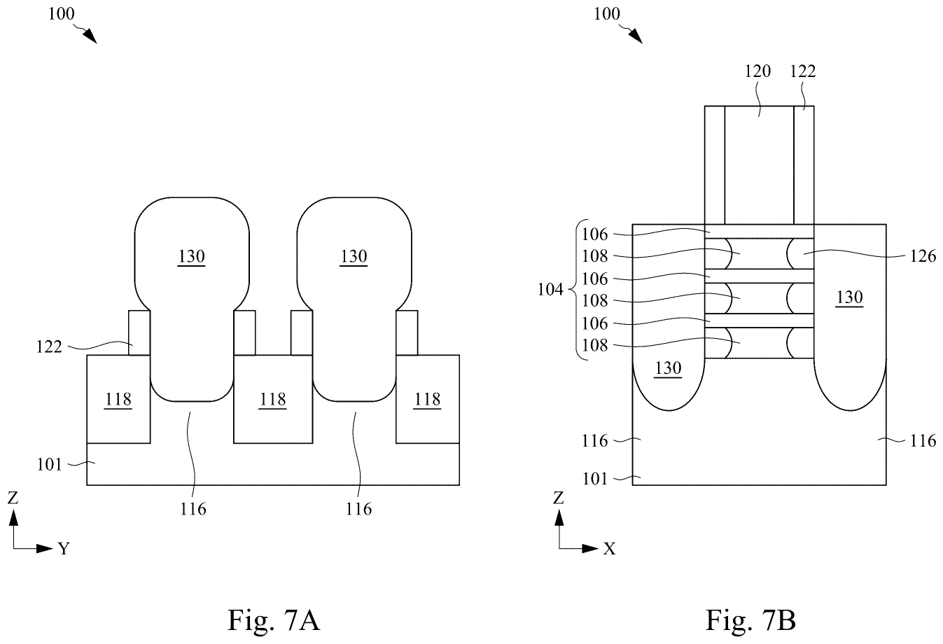

Next, as shown in FIGS. 7A and 7B, source/drain (S/D) regions 130 are formed from the substrate portion 116. The S/D regions 130 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 130 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 130. The S/D regions 130 may be formed by an epitaxial growth method using CVD, ALD or MBE.

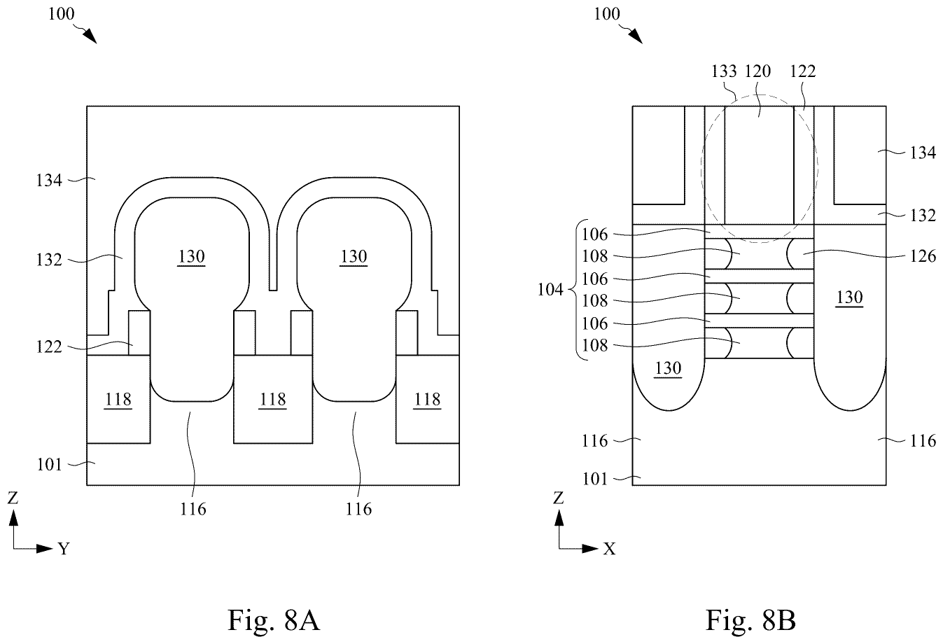

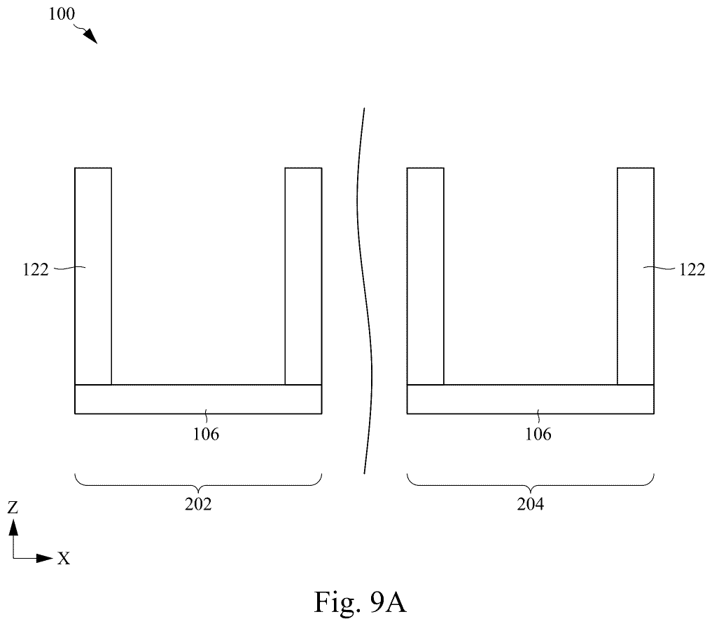

As shown in FIGS. 8A and 8B, a contact etch stop layer (CESL) 132 is conformally formed on the exposed surfaces of the semiconductor device structure 100. The CESL 132 covers the sidewalls of the sacrificial gate structure, the isolation regions 118, the S/D regions 130, and the dielectric layer 124. The CESL 132 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 134 is formed on the CESL 132 over the semiconductor device structure 100. The materials for the ILD layer 134 may include compounds including Si, O, C, and/or H, such as silicon oxide, SiCOH, or SiOC. Organic materials, such as polymers, may also be used for the ILD layer 134. The ILD layer 134 may be deposited by a PECVD process or other suitable deposition technique. In some embodiments, after formation of the ILD layer 134, the semiconductor device structure 100 may be subject to a thermal process to anneal the ILD layer 134.

After the ILD layer 164 is formed, a planarization operation, such as CMP, is performed on the semiconductor device structure 100 until the sacrificial gate electrode 120 is exposed, as shown in FIGS. 8A and 8B.

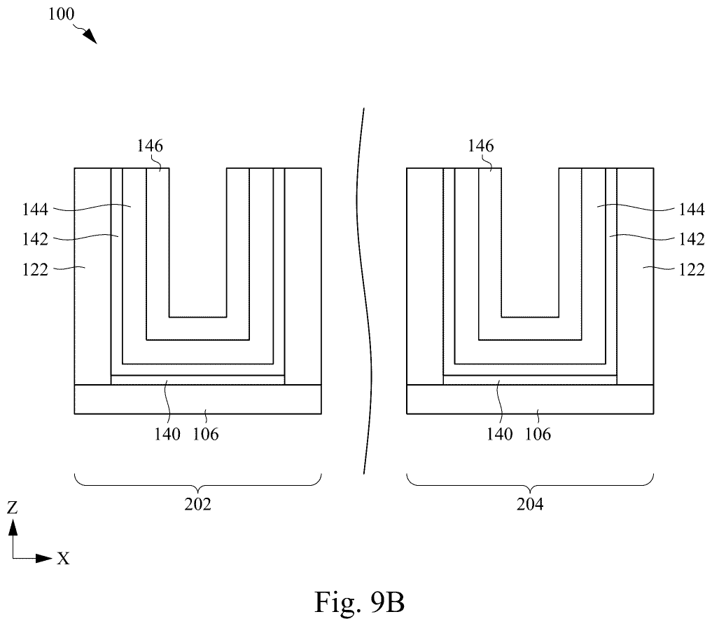

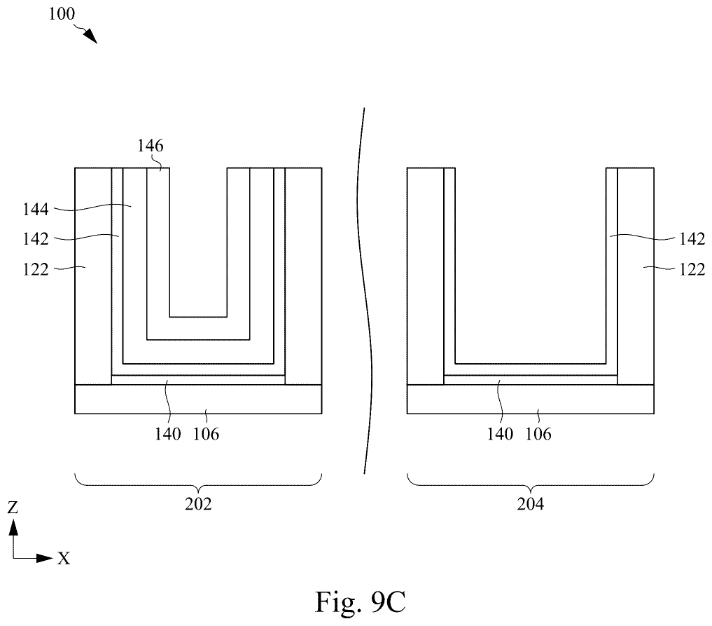

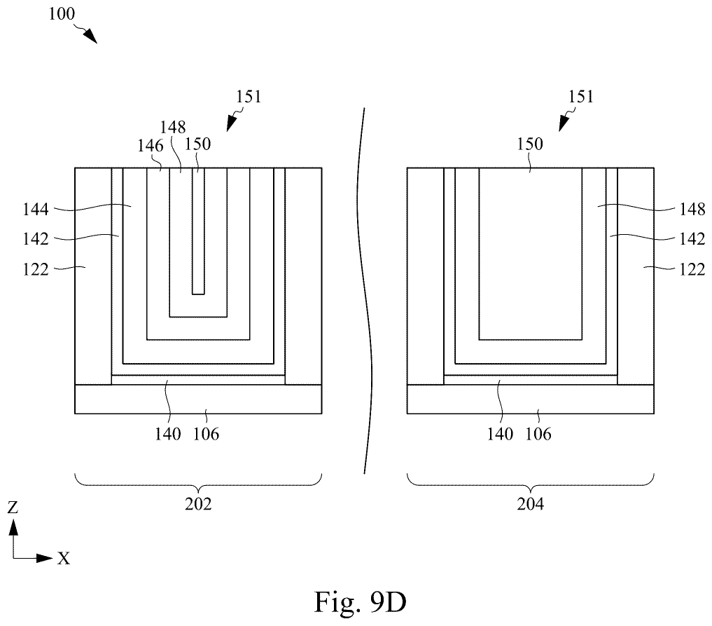

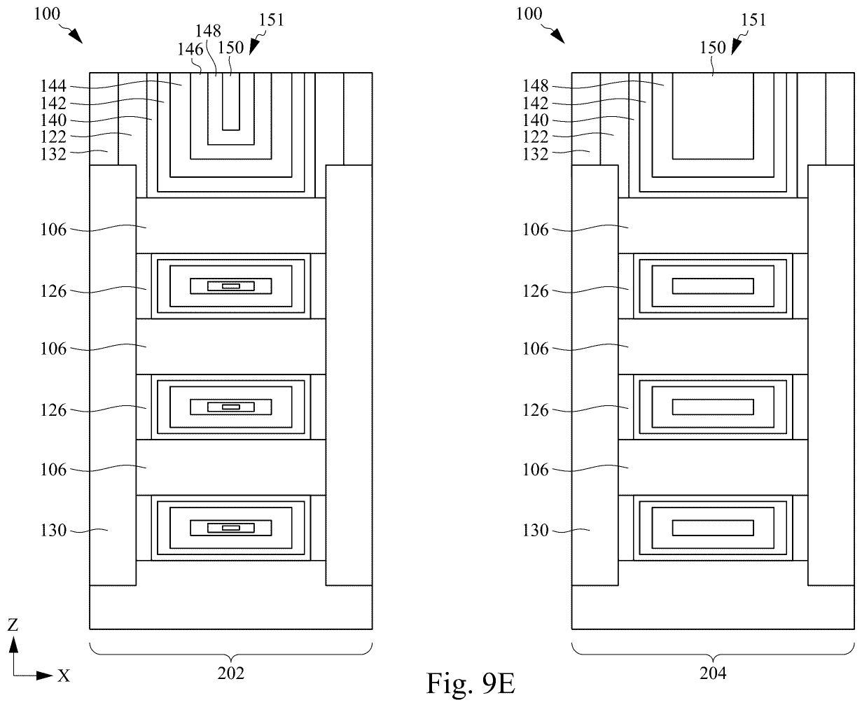

FIG. 9A-9E are cross-sectional side views of various stages of manufacturing the semiconductor device structure 100, in accordance with some embodiments. FIG. 9A-9D illustrate a portion 133 of the semiconductor device structure 100 during various stages of manufacturing the semiconductor device structure 100. As shown in FIG. 9A, the semiconductor device structure 100 includes a first region 202 and a second region 204. The first and second regions 202, 204 are disposed over the substrate 101 (FIG. 8B). In some embodiments, the first region 202 includes transistors with controlled threshold voltage, while the second region 204 includes transistors with reduced electrical resistance. As shown in FIG. 9A, the sacrificial gate structure and the second semiconductor layers 108 are removed in both first and second regions 202, 204. The removal of the sacrificial gate structure and the semiconductor layers 108 forms an opening between gate spacers 122 and between first semiconductor layers 106. The ILD layer 134 protects the S/D regions 130 during the removal processes. The sacrificial gate structure can be removed using plasma dry etching and/or wet etching. The sacrificial gate electrode 120 may be first removed by any suitable process, such as dry etch, wet etch, or a combination thereof, followed by the removal of the sacrificial gate dielectric layer, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode 120 but not the gate spacers 122, the ILD layer 134, and the CESL 132. In some embodiments, the etch process to remove the sacrificial gate dielectric layer may also remove a portion of the native oxide layer located under the gate spacer 122.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si and the dielectric materials of the gate spacers 122 and the isolation regions 118. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

Next, as shown in FIG. 9B, after the formation of the nanostructure channels (i.e., the exposed portions of the first semiconductor layers 106), an interfacial layer (IL) 140 and a gate dielectric layer 142 are formed to surround the exposed portions of the first semiconductor layers 106. In some embodiments, the IL 140 is selectively formed on the exposed portions of the first semiconductor layers 106, and the gate dielectric layer 142 is then formed on the IL 140 and the isolation regions 118. In some embodiments, the IL 140 is formed under the gate spacer 122, as a result of the removal of a portion of the native oxide layer during the removal of the sacrificial gate dielectric layer. In some embodiments, the IL 140 includes an oxide, such as silicon oxide. In some embodiments, the gate dielectric layer 142 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 131 may be formed by CVD, ALD or any suitable deposition technique.

In some embodiments, one or more work function layers, such as a first work function layer 144 and a second work function layer 146, are formed on the gate dielectric layer 142 between the gate spacers 120, as shown in FIG. 9B. The materials for the work function layers 144, 146 may be chosen based upon the type of device to be formed. Exemplary p-type work function materials may include Al, TiAlC, TiN, TaN, Ru, Mo, WN, ZrSi₂, MoSi₂, TaSi₂, NiSi₂, other suitable p-type work function materials, or combinations thereof. Exemplary n-type work function materials may include Ti, TiAl, Ag, TaAl, TaAlC, TiAlN, TaC, TaCN, TaSiN, Mn, Zr, other suitable n-type work function materials, or combinations thereof. A work function value is associated with the material composition of each of the work function layers 144, 146, and thus, the material of each of the work function layers 144, 146 is chosen to tune its work function value so that a predetermined threshold voltage is achieved in the device that is to be formed in one or more regions of the semiconductor device structure 100. The work function layers 144, 146 may be deposited by CVD, PVD, and/or other suitable process to a thickness of between about 5 Angstroms and about 50 Angstroms. In some embodiments, the first work function layer 144 is made of or include TiN or TaN, and the second work function layer 146 is made of or include TiAl.

As shown in FIG. 9B, the one or more work function layers 144, 146 are initially formed in both first and second regions 202, 204. In some embodiments, the devices formed in the second region 204 do not need the one or more work function layers 144, 146 to tune the work function value to achieve a predetermined threshold voltage. Thus, in some embodiments, a mask (not shown) is formed in the first region 202, and the one or more work function layers 144, 146 formed in the second region 204 are removed, as shown in FIG. 9C. The one or more work function layers 144, 146 located in the second region 204 may be removed by any suitable process. In some embodiments, one or more selective etching processes may be performed to remove the one or more work function layers 144, 146. The one or more selective etching processes do not substantially affect the mask (not shown) formed in the first region 202, the gate dielectric layer 142, the gate spacers 120, and the ILD layer 134 (FIG. 8B). After the removal of the one or more work function layers 144, 146 located in the second region 204, the mask (not shown) formed in the first region 202 is removed.

As shown in FIG. 9D, a glue layer 148 is formed on the one or more work function layers 144, 146 in the first region 202 and on the gate dielectric layer 142 in the second region 204, and a gate electrode layer 150 is formed on the glue layer 148 in both first and second regions 202, 204. In some embodiments, the glue layer 148 ensures the gate electrode layer 150 is adhered to the semiconductor device structure 100. In some embodiments, the glue layer 148 is made of or include TiN, and the gate electrode layer 150 is made of or includes an electrically conductive material, such as a metal. The glue layer 148 may be formed by any suitable process, such as ALD, and the gate electrode layer 150 may be formed by any suitable process, such as PVD, ALD, or electro-plating. In some embodiments, the glue layer 148 is optional, the gate electrode layer 150 is disposed on and in contact with the second work function layer 146 in the first region 202, and the gate electrode layer 150 is disposed on and in contact with the gate dielectric layer 142 in the second region 204. In the first region 202, the gate dielectric layer 142, the one or more work function layers 144, 146, the glue layer 148, and the gate electrode layer 150 may together form a gate structure 151. In the second region 204, the gate structure 151 includes the gate dielectric layer 142, the glue layer 148, and the gate electrode layer 150. In some embodiments, the gate electrode layer 150 is made of a material that has a lower electrical resistance than the one or more work function layers 144, 146. For example, the gate electrode layer 150 is made of W, Cu, Ru, Co, or other suitable material. In some embodiments, at least one of the one or more work function layers 144, 146 of the gate structure 151 located in the first region 202 includes aluminum, and the gate structure 151 located in the second region 204 is free of aluminum (Al). In some embodiments, the semiconductor device structure 100 includes the first region 202 having devices, such as transistors, with controlled threshold voltage and the second region 204 having devices with reduced electrical resistance compared to the devices of the first region 202. In some embodiments, the electrical resistance of the gate structure 151 located in the second region 204 is lower than that of the gate structure 151 located in the first region 202 by about 30 percent to about 50 percent, and the ring oscillator speed gain of the devices in the second region 204 is about eight percent to about 10 percent compared to that of the devices in the first region 202.

After the deposition of the gate electrode layer 150, a planarization process, such as a CMP process, may be performed to remove portions of the glue layer 148 and gate electrode layer 150 formed over the ILD layer 134 (FIG. 8B).

As described above, while the embodiments of this disclosure are discussed with respect to nanostructure channel FETs, implementations of some aspects of the present disclosure may be used in other processes and/or in other devices, such as FinFETs, planar FETs, and other suitable devices. Thus, in some embodiments, the processes described in FIG. 9A-9D are applied to a FinFET structure or a planar FET structure. For example, the gate structures 151 in the first and second regions 202, 204 covers top and sidewalls of fins of a FinFET structure.

FIG. 9E is a cross-sectional side view of the gate structures 151 of nanostructure channel FETs. As shown in FIG. 9E, in some embodiment, the IL 140 is a conformal layer that is also formed on the gate spacers 122 and the dielectric spacers 126. The gate structure 151 located in the first region 202 is also formed between vertically adjacent first semiconductor layers 106. In other words, the gate structure 151, which includes the gate dielectric layer 142, the one or more work function layers 144, 146, the glue layer 148, and the gate electrode layer 150, surrounds a portion of each of the first semiconductor layers 106 located in the first region 202. Similarly, the gate structure 151 located in the second region 204 is also formed between vertically adjacent first semiconductor layers 106. In other words, the gate structure 151, which includes the gate dielectric layer 142, the glue layer 148, and the gate electrode layer 150, surrounds a portion of each of the first semiconductor layers 106 located in the second region 204.

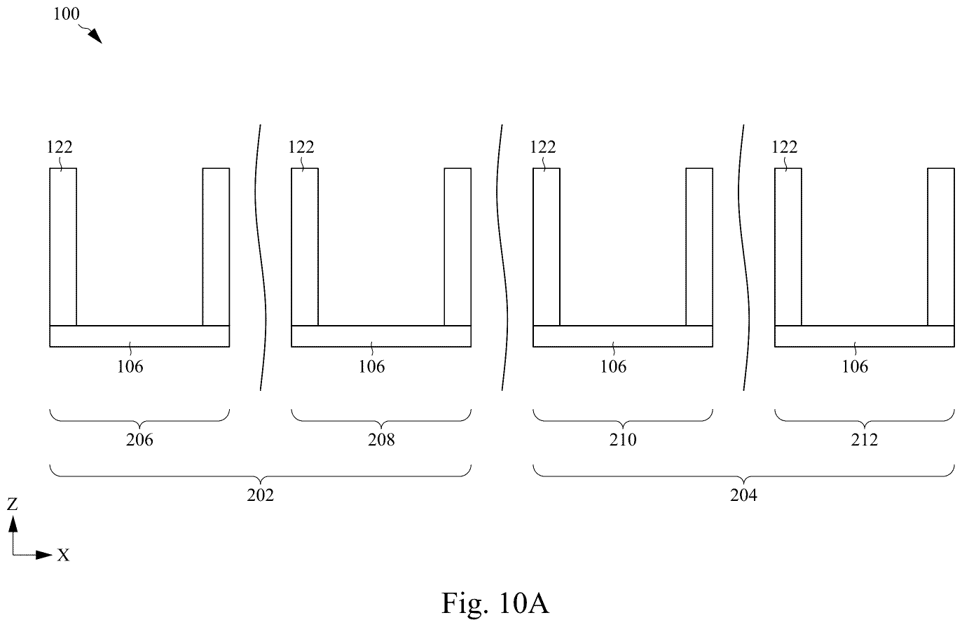

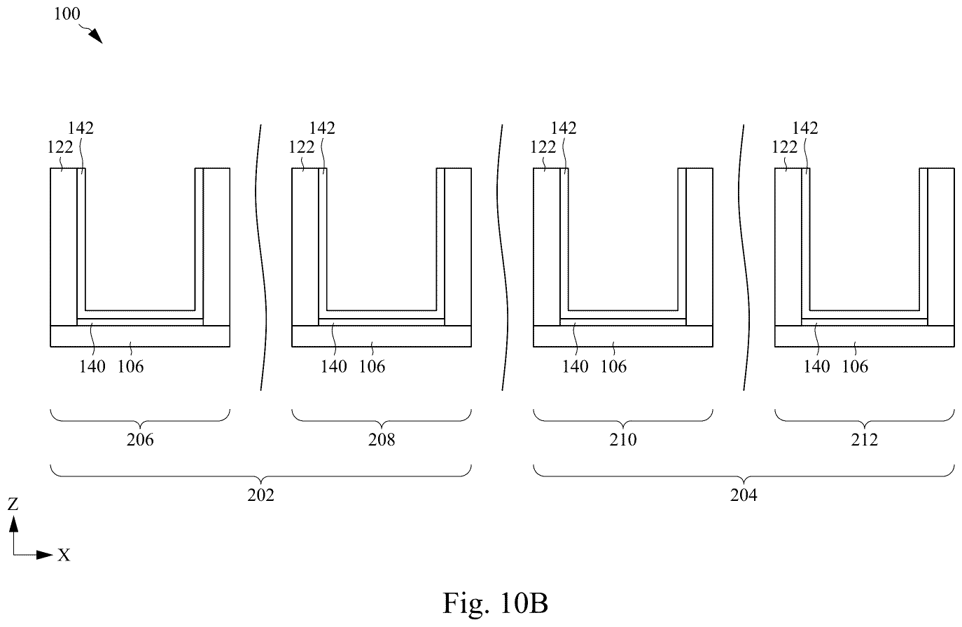

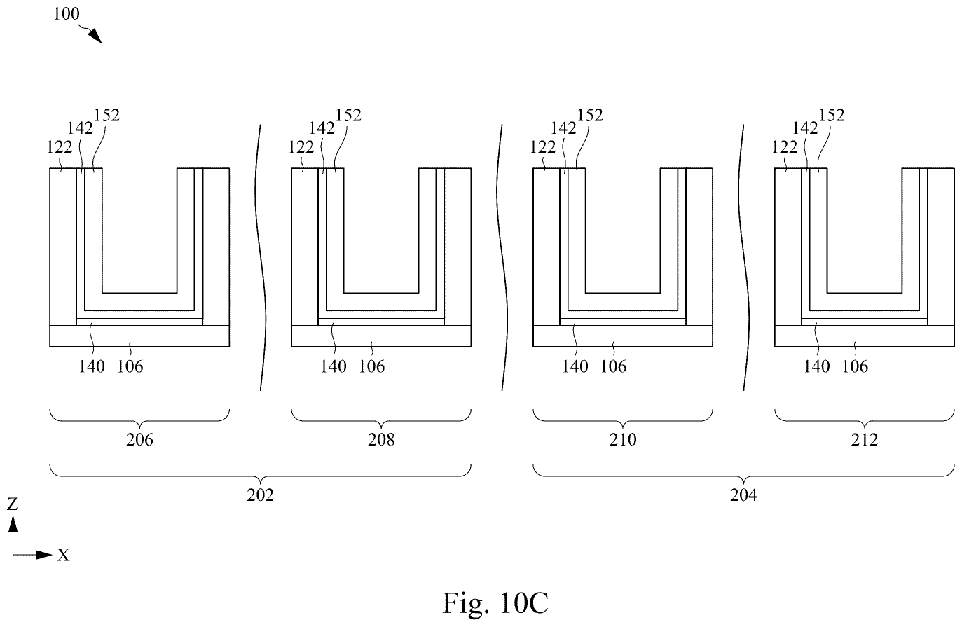

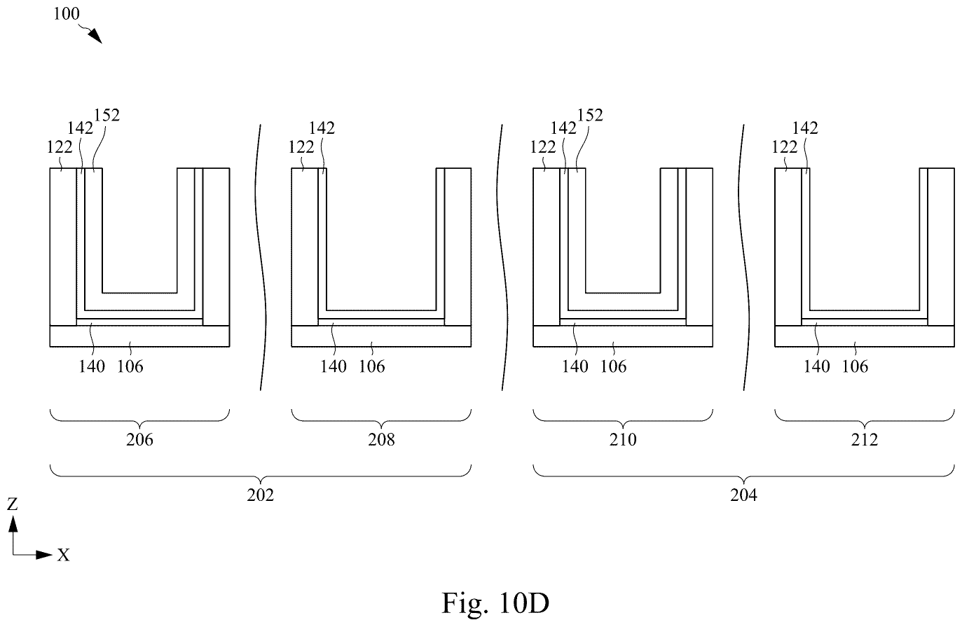

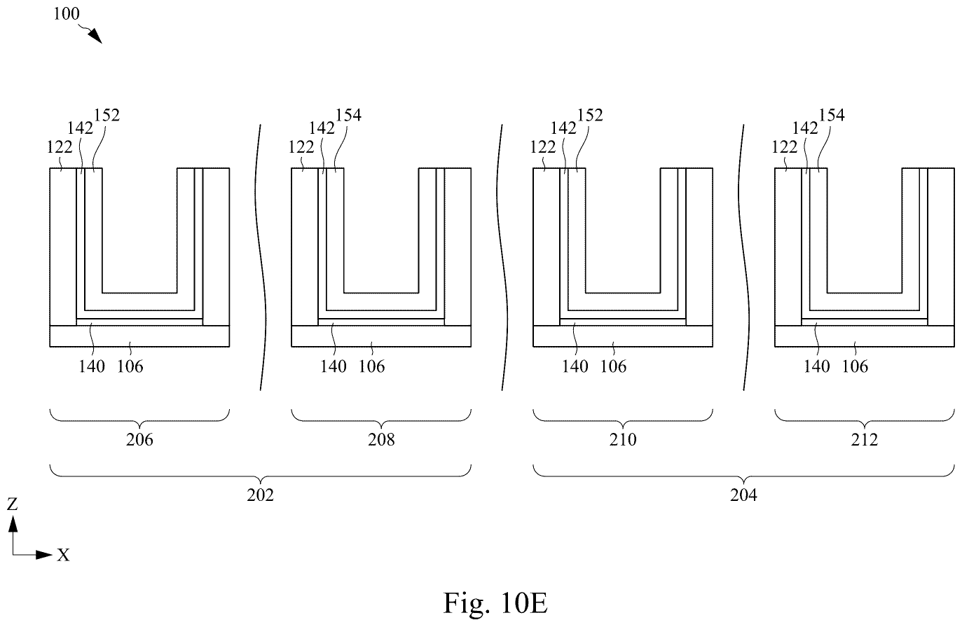

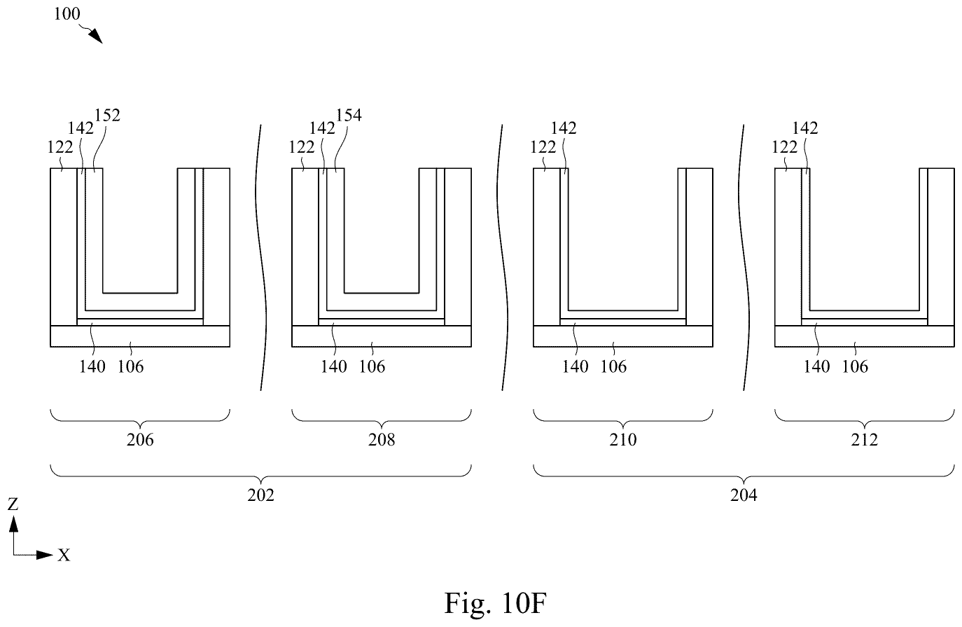

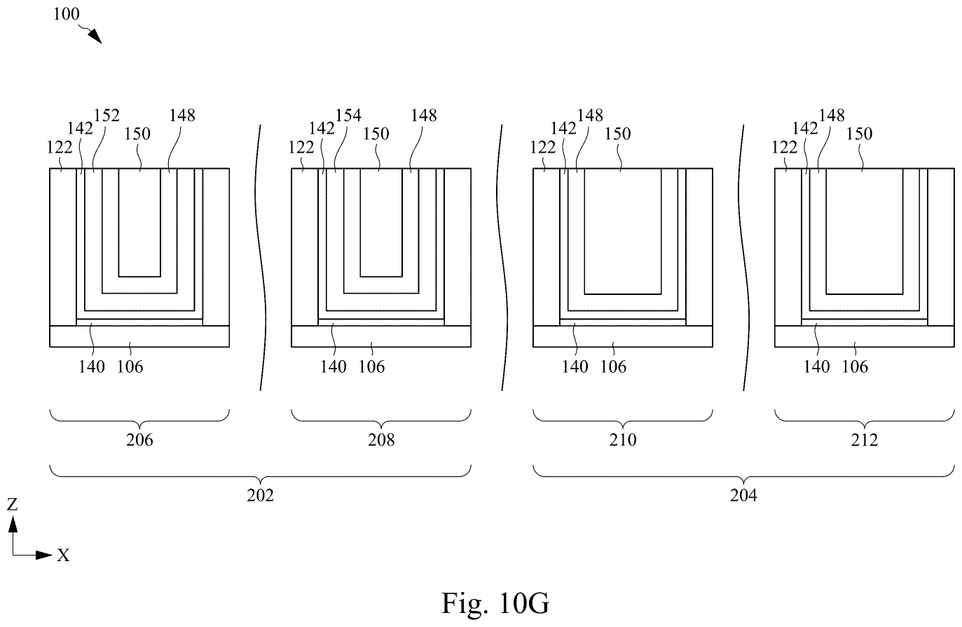

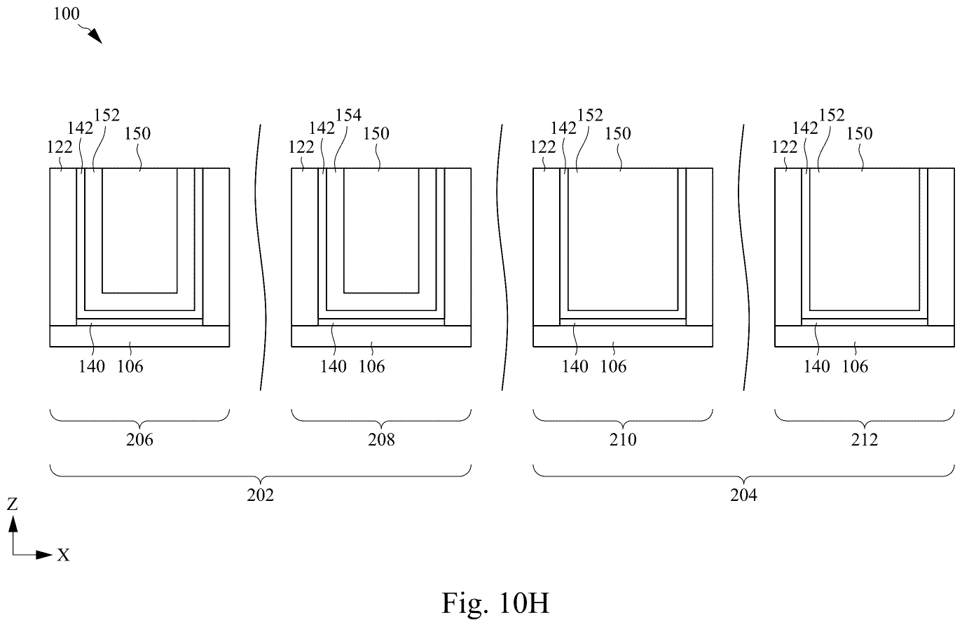

FIG. 10A-10H are cross-sectional side views of various stages of manufacturing the semiconductor device structure 100, in accordance with alternative embodiments. FIG. 10A-10H illustrate the portion 133 of the semiconductor device structure 100 during various stages of manufacturing the semiconductor device structure 100, in accordance with alternative embodiments. In some embodiments, regions of the semiconductor device structure 100 in which n-type devices or p-type devices are formed are respectively referred to herein as “NMOS regions” or “PMOS regions.” As shown in FIG. 10A, the semiconductor device structure 100 include the first and second regions 202, 204. In some embodiments, the first region 202 includes a PMOS region 206 and an NMOS region 208, and the second region 204 includes a PMOS region 210 and an NMOS region 212. As shown in FIG. 10A, the sacrificial gate structure and the second semiconductor layers 108 are removed in the PMOS region 206 and NMOS region 208 of the first region 202 and in the PMOS region 210 and NMOS region 212 of the second region 204.

As shown in FIG. 10B, the IL 140 and the gate dielectric layer 142 are formed in the PMOS region 206 and NMOS region 208 of the first region 202 and in the PMOS region 210 and NMOS region 212 of the second region 204. As shown in FIG. 10C, one or more p-type work function layers 152 are formed in the PMOS region 206 and NMOS region 208 of the first region 202 and in the PMOS region 210 and NMOS region 212 of the second region 204. The one or more p-type work function layers 152 may include one or more layers of a p-type work function materials, and the one or more p-type work function layers 152 may be formed by any suitable process, such as ALD. In some embodiments, the one or more p-type work function layers 152 is a single layer of a p-type work function material. As shown in FIG. 10D, the one or more p-type work function layers 152 located in the NMOS regions 208, 212 of the first and second regions 202, 204, respectively, are removed. A mask (not shown) may be first formed in the PMOS regions 206, 210 of the first and second regions 202, 204, respectively, to protect the one or more p-type work function layers 152 located in the PMOS regions 206, 210. The removal of the one or more p-type work function layers 152 in the NMOS regions 208, 212 may be performed by an etch process, such as a selective etch process. The selective etch process does not substantially affect the mask (not shown), the gate spacers 120, the ILD layer 134 (FIG. 8B), and the gate dielectric layer 142.

As shown in FIG. 10E, one or more n-type work function layers 154 are deposited on the gate dielectric layer 142 located in the NMOS regions 208, 212 of the first and second regions 202, 204, respectively. The one or more n-type work function layers 154 may be also formed on the mask (not shown) located in the PMOS regions 206, 210 of the first and second regions 202, 204, respectively. The one or more n-type work function layers 154 may include one or more layers of an n-type work function materials, and the one or more n-type work function layers 154 may be formed by any suitable process, such as ALD. In some embodiments, the one or more n-type work function layers 154 is a single layer of an n-type work function material.

As shown in FIG. 10F, the mask formed in the PMOS regions 206, 210 of the first and second regions 202, 204, respectively, is removed, another mask (not shown) is formed in the PMOS region 206 and the NMOS region 208 of the first region 202, and the one or more p-type work function layers 152 located in the PMOS region 210 of the second region 204 and the one or more n-type work function layers 154 located in the NMOS region 212 of the second region 204 are removed. The removal of the one or more p-type work function layers 152 in the PMOS region 210 and the one or more n-type work function layers 154 in the NMOS region 212 may be performed by one or more etch processes, such as one or more selective etch processes. The selective etch processes do not substantially affect the mask (not shown), the gate spacers 120, the ILD layer 134 (FIG. 8B), and the gate dielectric layer 142.

As shown in FIG. 10G, the mask (not shown) located in the first region 202 is removed, and the glue layer 148 and the gate electrode layer 150 are deposited in the PMOS region 206 and the NMOS region 208 of the first region 202 and in the PMOS region 210 and the NMOS region 212 of the second region 204. In some embodiments, the glue layer 148 is not present, and the gate electrode layer 150 is deposited on and in contact with the one or more p-type work function layers 152 in the PMOS region 206 of the first region 202, the one or more n-type work function layers 154 in the NMOS region 208 of the first region 202, and the gate dielectric layer 142 in the PMOS region 210 and the NMOS region 212 of the second region 204, as shown in FIG. 10H.

After the deposition of the gate electrode layer 150, a planarization process, such as a CMP process, may be performed to remove portions of the glue layer 148 and gate electrode layer 150 formed over the ILD layer 134 (FIG. 8B), and the gate structures 151 are formed, as shown in FIGS. 10G and 10H.

As described above, while the embodiments of this disclosure are discussed with respect to nanostructure channel FETs, implementations of some aspects of the present disclosure may be used in other processes and/or in other devices, such as FinFETs, planar FETs, and other suitable devices. Thus, in some embodiments, the processes described in FIG. 10A-10H are applied to a FinFET structure or a planar FET structure. For example, the gate structures 151 in the first and second regions 202, 204 covers top and sidewalls of fins of a FinFET structure.

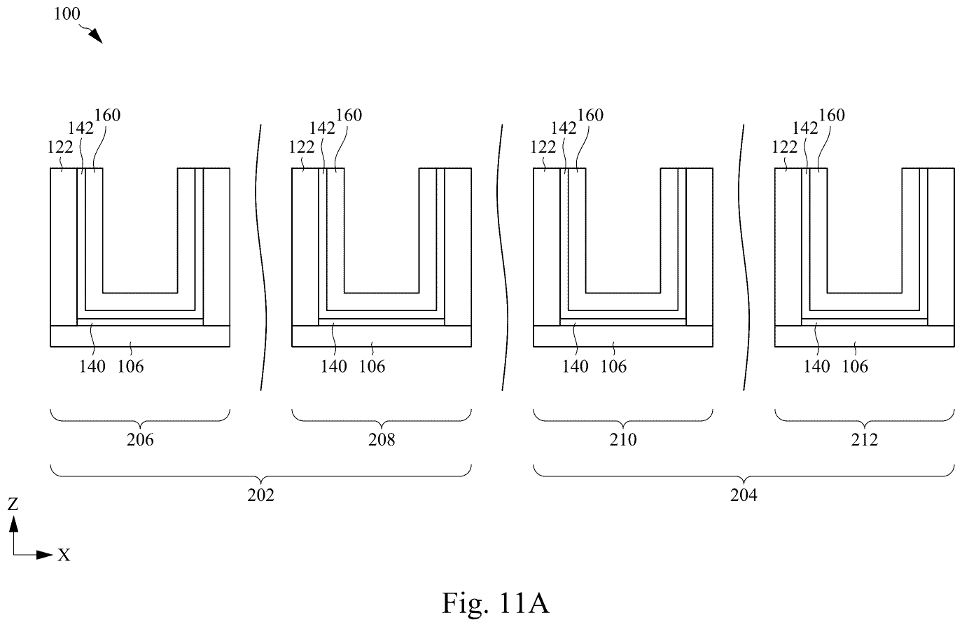

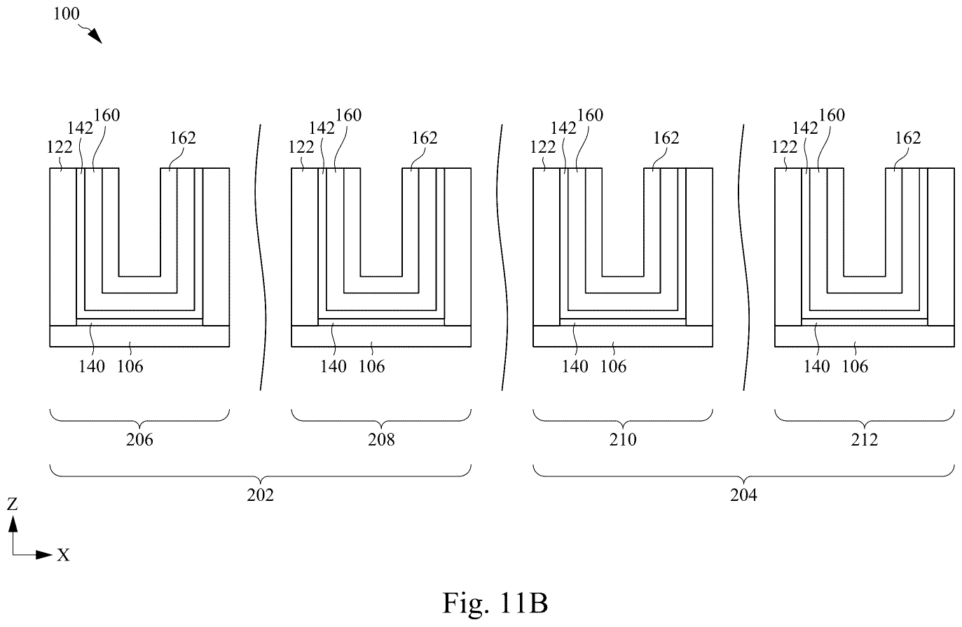

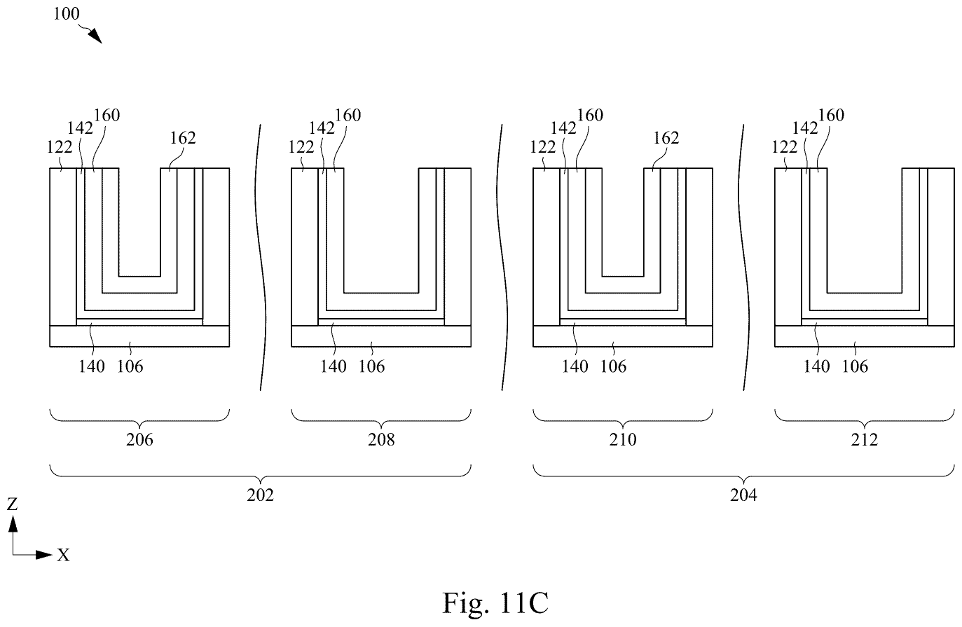

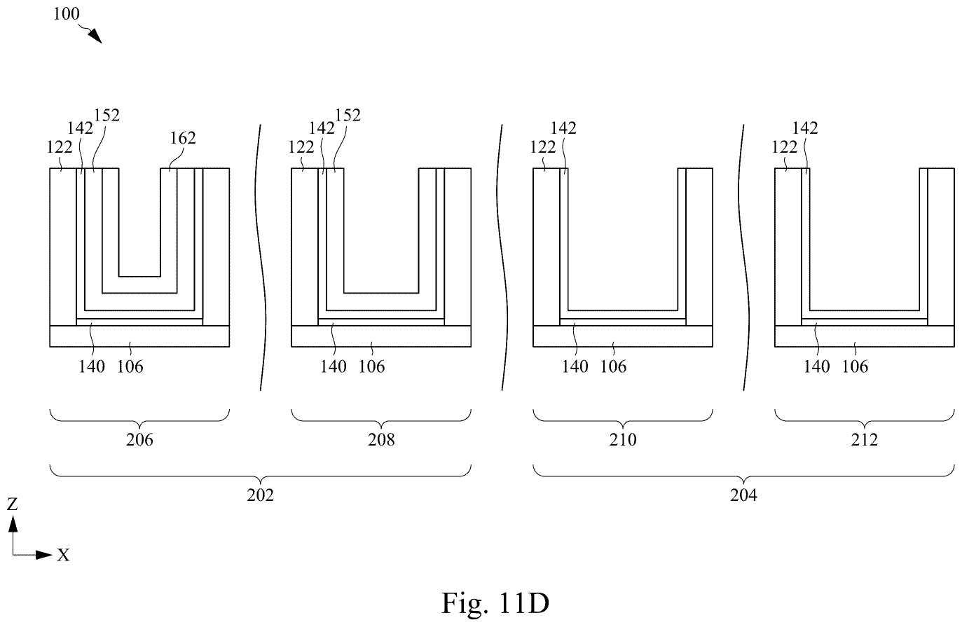

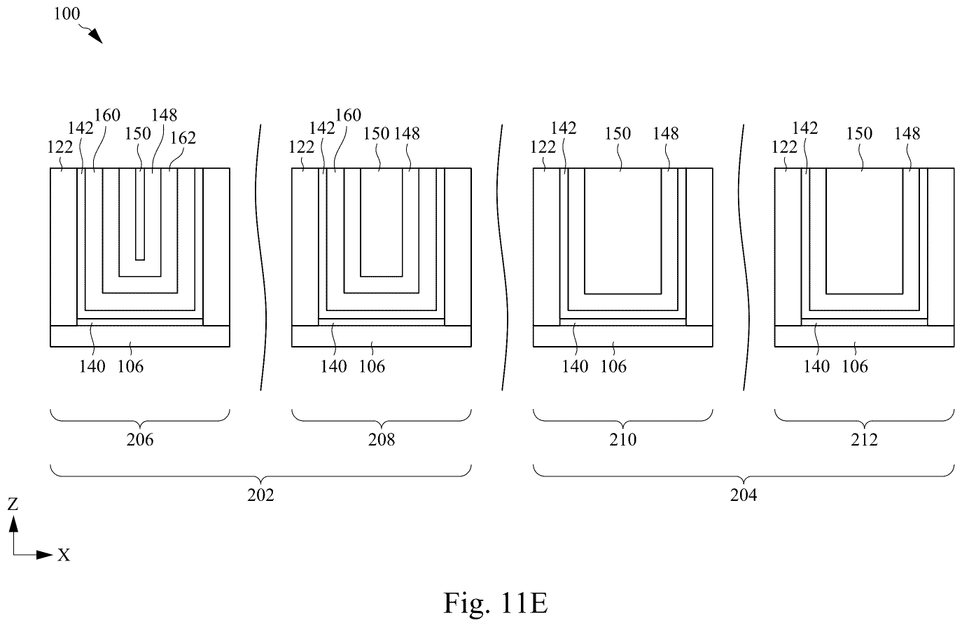

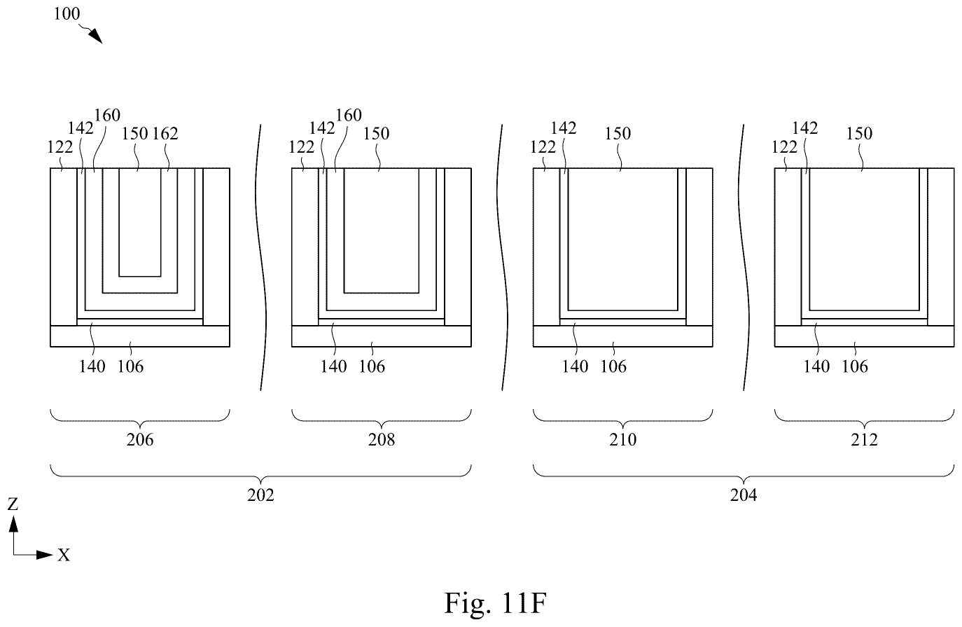

FIG. 11A-11F are cross-sectional side views of various stages of manufacturing the semiconductor device structure, in accordance with alternative embodiments. FIG. 11A-11F illustrate the portion 133 of the semiconductor device structure 100 during various stages of manufacturing the semiconductor device structure 100, in accordance with alternative embodiments. As shown in FIG. 11A, the IL 140 and the gate dielectric layer 142 are formed in the PMOS regions 206, 210 and the NMOS regions 208, 212 of the first and second regions 202, 204. In some embodiments, a first work function layer 160 is deposited on the gate dielectric layer 142 in the PMOS regions 206, 210 and the NMOS regions 208, 212 of the first and second regions 202, 204. The first work function layer 160 may be made of or include TiAl. The first work function layer 160 may be formed by a conformal process, such as ALD. In some embodiments, the first work function layer 160 includes an n-type work function material.

As shown in FIG. 11B, a second work function layer 162 is deposited on the gate dielectric layer 142 in the PMOS regions 206, 210 and the NMOS regions 208, 212 of the first and second regions 202, 204. In some embodiments, the second work function layer 162 may include a material different from that of the first work function layer 160. For example, the second work function layer 162 may be made of or include TiN. In some embodiments, the second work function layer 162 includes a p-type work function material. In some embodiments, the second work function layer 162 may be made of the same material as the first work function layer 160. The second work function layer 162 may be formed by a conformal process, such as ALD. As shown in FIG. 11C, the second work function layer 162 located in the NMOS regions 208, 212 of the first and second regions 202, 204, respectively, is removed. A mask (not shown) may be first formed in the PMOS regions 206, 210 of the first and second regions 202, 204, respectively, to protect the second work function layer 162 located in the PMOS regions 206, 210. The removal of the second work function layers 162 in the NMOS regions 208, 212 may be performed by an etch process, such as a selective etch process. The selective etch process does not substantially affect the mask (not shown), the gate spacers 120, the ILD layer 134 (FIG. 8B), and the gate dielectric layer 142.

As shown in FIG. 11D, the mask formed in the PMOS regions 206, 210 of the first and second regions 202, 204, respectively, is removed, another mask (not shown) is formed in the PMOS region 206 and the NMOS region 208 of the first region 202, and the first and second work function layers 160, 162 located in the PMOS region 210 of the second region 204 and the first work function layer 160 located in the NMOS region 212 of the second region 204 are removed. The removal of the first and second work function layers 160, 162 in the PMOS region 210 and the first work function layer 160 in the NMOS region 212 may be performed by one or more etch processes, such as one or more selective etch processes. The selective etch processes do not substantially affect the mask (not shown), the gate spacers 120, the ILD layer 134 (FIG. 8B), and the gate dielectric layer 142.

As shown in FIG. 11E, the mask (not shown) located in the first region 202 is removed, and the glue layer 148 and the gate electrode layer 150 are deposited in the PMOS region 206 and the NMOS region 208 of the first region 202 and in the PMOS region 210 and the NMOS region 212 of the second region 204. In some embodiments, the first and second work function layers 160, 162 include the same material. Thus, the combined thickness of the first and second work function layers 160, 162 in the PMOS region 206 is substantially greater than a thickness of the first work function layer 160 in the NMOS region 208. In some embodiments, the glue layer 148 is not present, and the gate electrode layer 150 is deposited on and in contact with the second work function layer 162 in the PMOS region 206 of the first region 202, the first work function layer 160 in the NMOS region 208 of the first region 202, and the gate dielectric layer 142 in the PMOS region 210 and the NMOS region 212 of the second region 204, as shown in FIG. 11F.

After the deposition of the gate electrode layer 150, a planarization process, such as a CMP process, may be performed to remove portions of the glue layer 148 and gate electrode layer 150 formed over the ILD layer 134 (FIG. 8B), and the gate structures 151 are formed, as shown in FIGS. 11E and 11F.

As described above, while the embodiments of this disclosure are discussed with respect to nanostructure channel FETs, implementations of some aspects of the present disclosure may be used in other processes and/or in other devices, such as FinFETs, planar FETs, and other suitable devices. Thus, in some embodiments, the processes described in FIG. 11A-11F are applied to a FinFET structure or a planar FET structure. For example, the gate structures 151 in the first and second regions 202, 204 covers top and sidewalls of fins of a FinFET structure.

In some embodiments, the semiconductor device structure 100 includes the first region including devices having controlled threshold voltage and the second region including devices having reduced electrical resistance. As a result, the overall electrical resistance of the semiconductor device structure 100 is reduced.

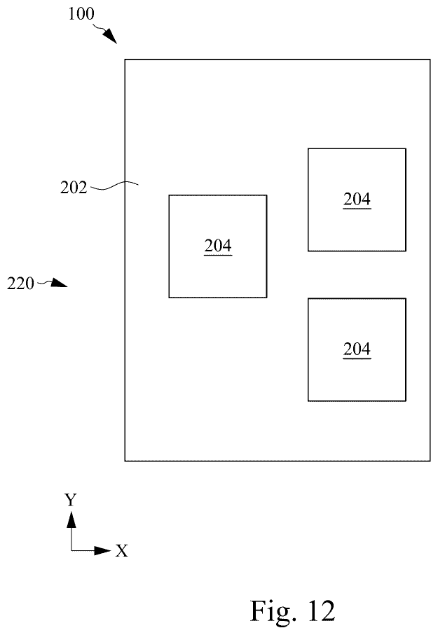

FIG. 12 is a top view of the semiconductor device structure 100, in accordance with some embodiments. As shown in FIG. 12, the semiconductor device structure 100 may be a chip 220 including one or more first regions 202 and one or more second regions 204. With the one or more second regions 204, the electrical resistance of the chip 220 is reduced.

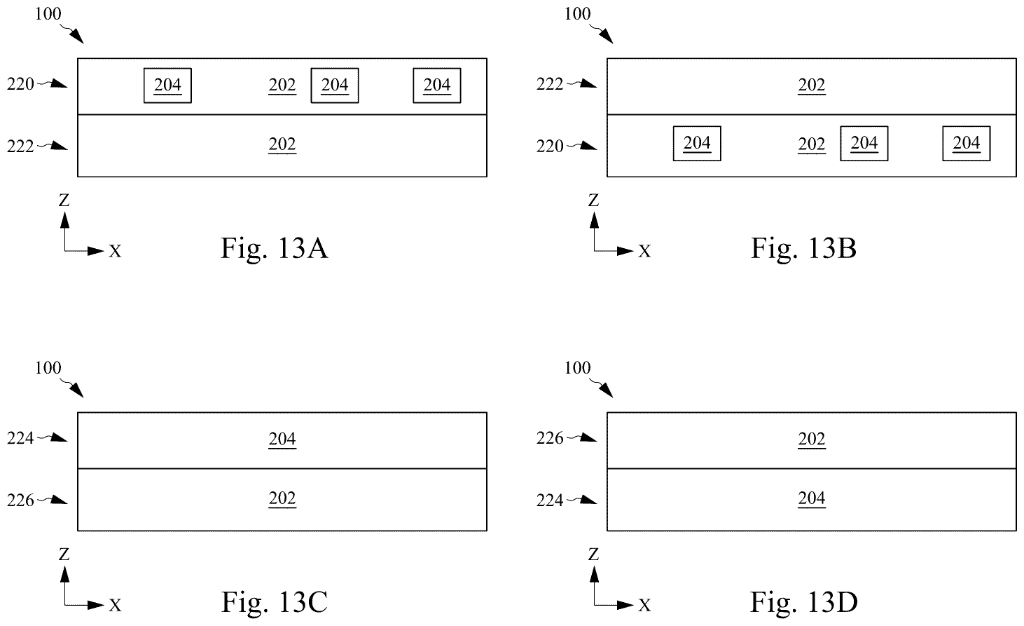

FIG. 13A-13D are cross-sectional side views of the semiconductor device structure 100, in accordance with some embodiments. In some embodiments, the semiconductor device structure 100 includes stacked chips, or three-dimensional ICs (3DICs), such as SoIC structures. The combinations of the first and second regions 202, 204 to reduce overall electrical resistance may be applied to the 3DICs in various ways. As shown in FIG. 13A, the semiconductor device structure 100 includes the chip 220 disposed on another chip 222. In some embodiments, the chip 220 includes both the first and second regions 202, 204, and the chip 222 includes the first region 202 but not the second region 204. Alternatively, the chip 222 includes the second region 204 but not the first region 202. As shown in FIG. 13B, the chip 222 is disposed on the chip 220. As shown in FIG. 13C, a first chip 224 is disposed on a second chip 226. In some embodiments, the first chip 224 includes the second region 204 but not the first region 202, and the second chip 226 includes the first region 202 but not the second region 204. In some embodiments, the first and second chips 224, 226 are formed from the same substrate (wafer). In other words, the first region 202 of the second chip 226 and the second region 204 of the first chip 224 are formed by the processes described in FIG. 9A-9E, 10A-10H, and 11A-11F. As shown in FIG. 13D, the second chip 226 is disposed on the first chip 224.

Embodiments of the present disclosure provide a semiconductor device structure and methods of forming the same. In some embodiments, the semiconductor device structure includes a first region 202 having one or more work function layers 144, 146 and a second region 204 free of the one or more work function layers 144, 146. Some embodiments may achieve advantages. For example, the one or more work function layers 144, 146 can tune the threshold voltage of the devices in the first region 202, while the electrical resistance of the devices in the second region 204 is lower than that of the devices in the first region 202. Furthermore, the overall electrical resistance of devices in both first and second regions 202, 204 is reduced.

An embodiment is a semiconductor device structure. The structure includes a first semiconductor layer disposed in a first region over a substrate, a gate dielectric layer disposed over the first semiconductor layer in the first region, one or more work function layers disposed on the gate dielectric layer in the first region, a glue layer disposed on the one or more work function layers in the first region, a gate electrode layer disposed on the glue layer in the first region, and a second semiconductor layer disposed in a second region over the substrate. The gate dielectric layer is disposed over the second semiconductor layer in the second region, the glue layer is disposed on the gate dielectric layer in the second region, and the gate electrode layer is disposed on the glue layer in the second region.

Another embodiment is a semiconductor device structure. The structure includes a first semiconductor layer disposed in a first region over a substrate, a gate dielectric layer disposed over the first semiconductor layer in the first region, one or more work function layers disposed on the gate dielectric layer in the first region, a gate electrode layer disposed on the one or more work function layers in the first region, and a second semiconductor layer disposed in a second region over the substrate. The gate dielectric layer is disposed over the second semiconductor layer in the second region, and the gate electrode layer is disposed on the gate dielectric layer in the second region.

A further embodiment is a method for forming a semiconductor device structure. The method includes depositing a first semiconductor layer in a first region over a substrate and a second semiconductor layer in a second region over the substrate, depositing a gate dielectric layer over the first semiconductor layer in the first region and over the second semiconductor layer in the second region, depositing one or more work function layers over the gate dielectric layer in the first region and over the gate dielectric layer in the second region, removing the one or more work function layers to expose the gate dielectric layer in the second region, and depositing a gate electrode layer over the one or more work function layers in the first region and over the gate dielectric layer in the second region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first semiconductor layer disposed in a first region over a substrate;
a gate dielectric layer disposed over the first semiconductor layer in the first region;
one or more work function layers disposed on the gate dielectric layer in the first region;
a glue layer disposed on the one or more work function layers in the first region;
a gate electrode layer disposed on the glue layer in the first region; and
a second semiconductor layer disposed in a second region over the substrate, wherein the gate dielectric layer is disposed over the second semiconductor layer in the second region, the glue layer is disposed on the gate dielectric layer in the second region, and the gate electrode layer is disposed on the glue layer in the second region.

2. The semiconductor device structure of claim 1, further comprising an interfacial layer disposed between the first semiconductor layer and the gate dielectric layer in the first region and between the second semiconductor layer and the gate dielectric layer in the second region.

3. The semiconductor device structure of claim 1, wherein the first region comprises a first PMOS region and a first NMOS region, and the second region comprises a second PMOS region and a second NMOS region.

4. The semiconductor device structure of claim 3, wherein the one or more work function layers comprises a p-type work function layer disposed in the first PMOS region and an n-type work function layer disposed in the first NMOS region.

5. The semiconductor device structure of claim 4, wherein the glue layer is in contact with the p-type work function layer in the first PMOS region and with the n-type work function layer in the first NMOS region.

6. The semiconductor device structure of claim 3, wherein the one or more work function layers comprises a first work function layer disposed in the first PMOS region and a second work function layer disposed on the first work function layer in the first PMOS region, and the first work function layer is disposed in the first NMOS region.

7. The semiconductor device structure of claim 6, wherein the first and second work function layers comprise different materials.

8. The semiconductor device structure of claim 6, wherein the first and second work function layers comprise a same material.

9. A semiconductor device structure, comprising:
a first semiconductor layer disposed in a first region over a substrate;
a gate dielectric layer disposed over the first semiconductor layer in the first region;
one or more work function layers disposed on the gate dielectric layer in the first region;
a gate electrode layer disposed on the one or more work function layers in the first region; and
a second semiconductor layer disposed in a second region over the substrate, wherein the gate dielectric layer is disposed over the second semiconductor layer in the second region, and the gate electrode layer is disposed on the gate dielectric layer in the second region.

10. The semiconductor device structure of claim 9, wherein the one or more work function layers comprise a first work function layer and a second work function layer disposed on the first work function layer.

11. The semiconductor device structure of claim 10, wherein the first work function layer comprises TiAl, and the second work function layer comprises TiN.

12. The semiconductor device structure of claim 9, further comprising a first gate structure disposed in the first region and a second gate structure disposed in the second region.

13. The semiconductor device structure of claim 12, wherein the first gate structure comprises the gate dielectric layer, the one or more work function layers, and the gate electrode layer, and the second gate structure comprises the gate dielectric layer and the gate electrode layer.

14. The semiconductor device structure of claim 13, wherein the first gate structure comprises aluminum, and the second gate structure is free of aluminum.

15. A method for forming a semiconductor device structure, comprising:
depositing a first semiconductor layer in a first region over a substrate and a second semiconductor layer in a second region over the substrate;
depositing a gate dielectric layer over the first semiconductor layer in the first region and over the second semiconductor layer in the second region;
depositing one or more work function layers over the gate dielectric layer in the first region and over the gate dielectric layer in the second region;
removing the one or more work function layers to expose the gate dielectric layer in the second region; and
depositing a gate electrode layer over the one or more work function layers in the first region and over the gate dielectric layer in the second region.

16. The method of claim 15, further comprising depositing a glue layer on and in contact with the one or more work function layers in the first region and on and in contact with the gate dielectric layer in the second region, wherein the gate electrode layer is deposited on and in contact with the glue layer in the first and second regions.

17. The method of claim 15, wherein the first region comprises a first PMOS region and a first NMOS region, and the second region comprises a second PMOS region and a second NMOS region.

18. The method of claim 17, wherein the one or more work function layers comprises a p-type work function layer, the p-type work function layer is deposited in the first PMOS region, the first NMOS region, the second PMOS region, and the second NMOS region, and the p-type work function layer is removed in the first and second NMOS regions.

19. The method of claim 18, further comprising:
depositing an n-type work function layer in the first and second NMOS regions;
removing the p-type work function layer in the second PMOS region; and
removing the n-type work function layer in the second NMOS region.

20. The method of claim 17, wherein the one or more work function layers comprises a first work function layer and a second work function layer disposed on the first work function layer, and the first and second work function layers are removed in the second PMOS region and the second NMOS region.
